(19) United States
(12) Patent Application Publication
(10) Pub. No.: US 2026/0354289 A1
(43) Pub. Date: Nov. 5, 2026

(54) HIGH THROUGHPUT TWO-STAGE DIE-TO-WAFER THERMAL COMPRESSION BONDING SCHEME FOR HETEROGENEOUS INTEGRATION

(71) Applicant: The Regents of the University of California, Oakland, CA (US)

(72) Inventors: Subramanian IYER, Los Angeles, CA (US); Krutikesh SAHOO, Los Angeles, CA (US); Haoxiang REN, Los Angeles, CA (US)

(73) Assignee: The Regents of the University of California, Oakland, CA (US)

(21) Appl. No.: 19/488,582

(22) PCT Filed: May 29, 2024
(86) PCT No.: PCT/US2024/031474

§ 371 Date: Nov. 26, 2025

Related U.S. Application Data
(60) Provisional application No. 63/504,994, filed on May 30, 2023.

(51) Int. Cl. H10W 90/00; H10W 20/20; H10W 70/63; H10W 74/00

(52) U.S. Cl. CPC H10W 90/794; H10W 20/211; H10W 70/635; H10W 74/00

(57) ABSTRACT

The present embodiments relate to a methodology for high throughput face-to-face heterogeneous dielet bonding to be used in dielet assembly on interposers, wafer-scale and other advanced packaging constructs. The system includes: (1) a substrate having a front side and a backside; (2) a front side of the substrate with multiple patterned metal layers terminating in metal bumps; (3) a backside of the substrate which may have a flat surface attaching to a thermal dissipation unit; (3) a plurality of dielets which are face-to-face bonded to the metal bumps on the substrate using the proposed high-throughput thermal compression bonding; (4) an inorganic material encapsulating the assembled system; (5) a dielectric material adding on top of the encapsulated system to fill the trenches in between of the dielets; (6) a power/signal platform to power the dies/dielets of the assembly and transfer signals in and out of the assembled system; and (7) a solder-based connection between the power/signal platform and the encapsulated assembled system.

### CROSS-REFERENCE TO RELATED APPLICATIONS

The present application claims priority to U.S. Provisional Patent Application No. 63/504,994 filed May 30, 2023, the contents of which are incorporated herein by reference in their entirety.

### STATEMENT OF GOVERNMENT SPONSORED RESEARCH

This invention was made with government support under 2231097 awarded by the National Science Foundation. The government has certain rights in the invention.

### TECHNICAL FIELD

The present embodiments relate generally to electronic device packaging, and more particularly to high throughput face-to-face heterogeneous dielet bonding to be used in dielet assembly on interposers, wafer-scale and other advanced packaging constructs.

### BACKGROUND

Package scaling is necessary to satisfy the growing demands of processor-to-memory bandwidth and memory capacity, especially in high performance computing (HPC) applications. This is usually achieved by reducing bump-to-bump pitch in advanced packages including glass and silicon interposers, wafer-scale silicon packages, as well as flexible fanout packages. Scaling down bump pitches to 10 μm and below has the potential to offer several terabytes (TBs) of processor to memory bandwidth, however, it can only be achieved on silicon-based substrates, and by using advanced solderless bonding techniques (e.g. Subramanian S. Iyer, “Heterogeneous Integration for Performance and Scaling,” in IEEE Transactions on Components, Packaging and Manufacturing Technology, vol. 6, no. 7, pp. 973-982, July 2016. doi: 10.1109/TCPMT.2015.2511626).

Two bonding methods are currently being evaluated for sub-10 μm fine-pitch heterogeneous integration, with throughput, process simplicity and yield being the critical considerations. These methods are hybrid bonding and thermal compression bonding, both of which can be accomplished in die-to-die and die-to-substrate formats. Of the two bonding approaches, copper/dielectric hybrid bonding (HB) process has strict processing requirements. Meticulous control of dielectric roughness and metal recess is critical for hybrid bonding as discussed in (H. Ren, Y.-T. Yang, G. Ouyang, and S. S. Iyer, “Mechanism and Process Window Study for Die-to-Wafer (D2W) Hybrid Bonding,” in ECS Journal of Solid State Science and Technology, vol. 10, no. 6, 2021, https://doi.org/10.1149/2162-8777/ac0a52). Furthermore, particles generated during incorrect die or substrate handling can cause dielectric fractures after bonding and lead to assembly failure as described in A. Elsherbini et al., “Enabling Hybrid Bonding on Intel Process,” 2021 IEEE International Electron Devices Meeting (IEDM), 2021, pp. 34.3.1-34.3.4, doi: 10.1109/IEDM 19574.2021.9720586. In fact, plasma dicing is the choice of die/dielet segregation in hybrid bonding, specifically to reduce particle generation during dicing process. Overall, the hybrid bonding yield is very sensitive to particles as well as roughness parameters during assembly.

Direct copper-copper (Cu) thermal compression bonding (TCB) process, on the other hand, is relatively inexpensive, simpler and offers a reliable way to assemble dies/dielets on other dies or silicon substrates. In TCB, bondable pads/pillars are recessed to achieve metal-to-metal contact. There is no dielectric bonding. Topography on bonding pads is taken care of by temperature and pressure during bonding. Furthermore, TCB is not dependent on the type of dicing used, so inexpensive blade dicing is applicable. Finally, the level of particle control obtained through standard wet cleaning processes is ample for successful assembly. After bonding, an entire assembly is passivated by using a few nanometers of atomic-layer deposited (ALD) alumina, a process described in detail in N. Shakoorzadeh, K. Sahoo, Y.T. Yang, and S.S. Iyer, “Atomic Layer Deposited Al₂O₃ Encapsulation for the Silicon Interconnect Fabric,” 2020 IEEE 70th Electronic Components and Technology Conference (ECTC) (2020): 1241-1246, doi: 10.1109/ectc32862.2020.00198. This passivation layer protects any exposed Copper surfaces from further oxidation. Successful functional assemblies described in, for example, K. Sahoo, U. Rathore, S. Chandra Jangam, T. Nguyen, D. Markovic, S. S. Iyer, “Functional Demonstration of <0.4-pJ/bit, 9.8 μm Fine-Pitch Dielet-to-Dielet Links for Advanced Packaging using Silicon Interconnect Fabric,” 2022 IEEE 72nd Electronic Components and Technology Conference (ECTC), June 2022, have already demonstrated the mechanical and electrical reliability of die-to-substrate TCB.

One key challenge in TCB however, needs to be addressed to scale up TCB to multi-reticle interposer and wafer-scale silicon substrates. Throughput of conventional TCB is low, only about 90 units-per-hour (UPH), wherein unit may refer to a fabricated die or dielet or chiplet. Conventional TCB must be accomplished in single bonding step to achieve the requisite military standard shear strength per die/dielet (as prescribed in document MIL-STD-883G, available: http://everyspec.com/MIL-STD/MIL-STD-0800-0899/MIL-STD-883G_14587) as well as a low contact resistance (see S. C. Jangam and S. S. Iyer, “Silicon-Interconnect Fabric for Fine-pitch (≤10 μm) Heterogeneous Integration,” in IEEE Transactions on Components, Packaging and Manufacturing Technology, doi: 10.1109/TCPMT.2021.3075219) for reliable Cu—Cu interconnects. To achieve these requirements in a single step, a die/dielet tacking time of 30 seconds or greater is recommended. This allows for necessary grain growth to take place at Cu—Cu mating interfaces during TCB. However, the resulting throughput of 90 UPH makes conventional TCB unappealing from a perspective of high volume manufacturing (HVM).

It is against this technological backdrop that the present Applicant sought a technological solution to these and other problems rooted in this technology.

### SUMMARY

The present embodiments relate to high throughput face-to-face heterogeneous dielet bonding to be used in dielet assembly on interposers, wafer-scale and other advanced packaging constructs. A system in accordance with embodiments includes: (1) a substrate having a front side and a backside; (2) a front side of the substrate with multiple patterned metal layers terminating in metal bumps; (3) a backside of the substrate which may have a flat surface attaching to a thermal dissipation unit; (3) a plurality of dielets which are face-to-face bonded to the metal bumps on the substrate using the proposed high-throughput thermal compression bonding; (4) an inorganic material encapsulating the assembled system; (5) a dielectric material adding on top of the encapsulated system to fill the trenches in between of the dielets; (6) a power/signal platform to power the dies/dielets of the assembly and transfer signals in and out of the assembled system. (7) a solder-based connection between the power/signal platform and the encapsulated assembled system.

According to certain additional aspects, the present embodiments provide a methodology to increase throughput by >10× to more than 1100 UPH using a two-stage bonding approach. A first stage involves tacking all required dielets to the silicon substrate in a time ≤10 seconds. This step does not result in MIL-SPEC 883G specified bonding strength but ensures the assembled dies/dielets do not dislocate from their intended bonding sites during further processing. In a next stage, the complete assembly is annealed at optimized temperatures and pressures which raises the bonding strength of Cu—Cu interconnects to MIL-SPEC levels. Furthermore, grain growth takes place during this interval at the mating Cu—Cu interface to reduce contact resistance. By annealing multiple substrates at the same interval, annealing time can be eliminated as a throughput concern. This two-stage bonding approach can achieve a throughput of >1100 UPH.

### BRIEF DESCRIPTION OF THE DRAWINGS

These and other aspects and features of the present embodiments will become apparent to those ordinarily skilled in the art upon review of the following description of specific embodiments in conjunction with the accompanying figures, wherein:

FIG. 1 is a cross-sectional view of an example two-stage thermal compression bonding (TCB) between die/dielet and silicon-based substrate according to embodiments.

FIGS. 2A and 2B are block diagrams representing an example die/dielet and substrate respectively before the initiation of a high throughput thermal compression bonding process according to embodiments.

FIGS. 3A and 3B are block diagrams illustrating an example pre-bonding treatment to be done both on die and substrate side, respectively.

FIG. 4 is a cross-sectional view of an example process of preparing a die and substrate for tacking according to embodiments.

FIG. 5 is a diagram illustrating an example tacking process according to embodiments.

FIG. 6 illustrates an example wafer-scale substrate, or an interposer substrate populated with multiple dielets according to embodiments.

FIG. 7 is a diagram illustrating an example wafer-scale system in the process of annealing according to embodiments.

### DETAILED DESCRIPTION

The present embodiments will now be described in detail with reference to the drawings, which are provided as illustrative examples of the embodiments so as to enable those skilled in the art to practice the embodiments and alternatives apparent to those skilled in the art. Notably, the figures and examples below are not meant to limit the scope of the present embodiments to a single embodiment, but other embodiments are possible by way of interchange of some or all of the described or illustrated elements. Moreover, where certain elements of the present embodiments can be partially or fully implemented using known components, only those portions of such known components that are necessary for an understanding of the present embodiments will be described, and detailed descriptions of other portions of such known components will be omitted so as not to obscure the present embodiments. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the present disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present embodiments encompass present and future known equivalents to the known components referred to herein by way of illustration.

According to certain aspects, the present embodiments relate to a methodology for high throughput face-to-face heterogeneous dielet bonding to be used in dielet assembly on interposers, wafer-scale and other advanced packaging constructs.

As set forth above, package scaling is necessary to satisfy the growing demands of processor-to-memory bandwidth and memory capacity, especially in high performance computing (HPC) applications. This is usually achieved by reducing bump-to-bump pitch in advanced packages including glass and silicon interposers, wafer-scale silicon packages, as well as flexible fanout packages. Scaling down bump pitches to 10 μm and below has the potential to offer several terabytes (TBs) of processor to memory bandwidth, however, it can only be achieved on silicon-based substrates, and by using advanced solderless bonding techniques such as that described in Subramanian S. Iyer, “Heterogeneous Integration for Performance and Scaling,” in IEEE Transactions on Components, Packaging and Manufacturing Technology, vol. 6, no. 7, pp. 973-982, July 2016. doi: 10.1109/TCPMT.2015.2511626.

As further set forth above, a direct copper-copper (Cu) TCB process is relatively inexpensive, simpler and offers a reliable way to assemble dies/dielets on other dies or silicon substrates. However, throughput of conventional TCB is low, whereas a die/dielet tacking time of 30 seconds or greater is recommended. As a result, conventional TCB techniques are unappealing from a perspective of high volume manufacturing (HVM).

In accordance with certain aspects, therefore, the present embodiments provide a methodology to increase throughput by >10× to more than 1100 UPH using a two-stage bonding approach. The first stage involves tacking all required dielets to the silicon substrate in a time ≤10 seconds. This step does not result in MIL-SPEC 883G specified bonding strength but ensures the assembled dies/dielets do not dislocate from their intended bonding sites during further processing. In a next stage, the complete assembly is annealed at optimized temperatures and pressures which raises the bonding strength of Cu—Cu interconnects to MIL-SPEC levels. Furthermore, grain growth takes place during this interval at the mating Cu—Cu interface to reduce contact resistance. By annealing multiple substrates at the same interval, annealing time can be eliminated as a throughput concern. This two-stage bonding approach can achieve a throughput of >1100 UPH.

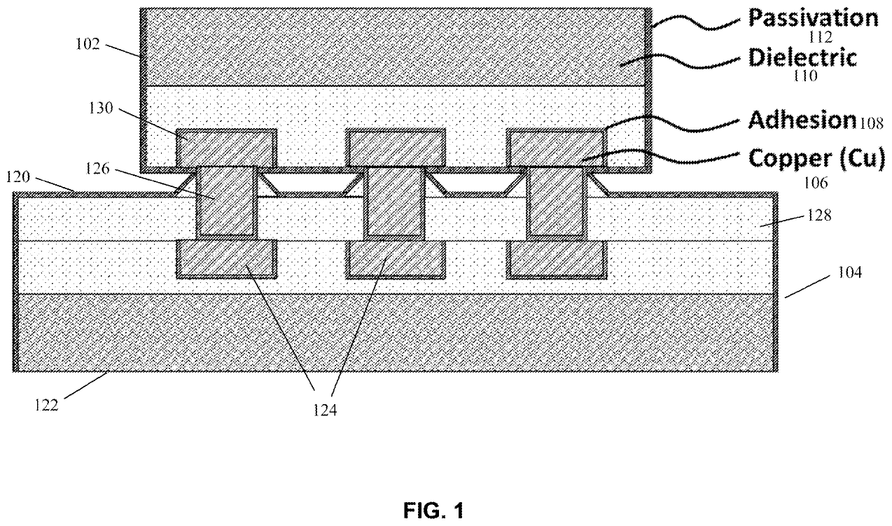

FIG. 1 is a cross-sectional view of an example two-stage thermal compression bonding (TCB) between die/dielet 102 and substrate 104 according to embodiments. Substrate 104 can be another die or an interposer or even a wafer-scale substrate. Substrate 104 can be a silicon substrate. Substrate 104 can be a wafer-scale advanced packaging substrate known as silicon-interconnect fabric (Si-IF) and can be extended to any silicon-interposer irrespective of its size. Improvements to account for different die thicknesses during bonding are possible.

Adhesion layer 108 is any standard Cu adhesion layer to dielectric such as Tantalum Nitride (TaN). Passivation 112 can comprise a few nanometers of atomically deposited alumina (Al₂O₃) deposited as described in N. Shakoorzadeh, K. Sahoo, Y. T. Yang, and S. S. Iyer, “Atomic Layer Deposited Al₂O3 Encapsulation for the Silicon Interconnect Fabric,” 2020 IEEE 70th Electronic Components and Technology Conference (ECTC) (2020): 1241-1246, doi: 10.1109/ectc32862.2020.00198.

As shown, substrate 104 has a front side 120 and a backside 122. The front side 122 of the substrate includes multiple patterned metal layers 124 terminating in metal bumps 126. The metal bumps 126 can comprise Cu pillars. The backside 122 of the substrate which may have a flat surface attaching to a thermal dissipation unit, for example. A dielectric layer 128 surrounds the terminating metal pads/pillars 126, which layer 128 is partially recessed. Layers 124 can be metal redistribution layers including wires for lateral inter-die communication, and are terminated with metal vias, pillars (126 as shown in FIG. 1), or pads. The metal vias, pillars, or pads can be further redistributed with building an additional layer of patterned metal for the electrical connection for the electroplating process. The metal redistribution layers can also include power and ground planes (or grids). The metal wires for inter-die signaling can be in dedicated layers or be shared with part of power/ground layers. The power/ground distribution layers can also connect to metal vias, pillars, or pads.

Dielet 102 is face-to-face bonded on the recessed metal pads/pillars 126 of the substrate using two-stage thermal compression bonding (TCB) process. An encapsulating material can encapsulate the assembled system. A power/signal platform may be placed either on below or above the assembly to transfer power and signals to the assembled dielets. A power/signal delivery which is henceforth referred to as substrate-side if power/signal delivery is placed below the assembly and dielet-side if power/signal delivery is placed above the assembly. The dielectric layer 128 may also fill gaps between assembled dies/dielets on the frontside 120 of the substrate to allow the fabrication of through dielet vias (TDVs), when the power/signal platform is placed above the die/dielets, enabling a front-side or dielet-side power delivery. Any Cu pads/pillars 126 not used for thermal compression bonding are buried in dielectric prior to bonding. The dielectric layer 128 can be recessed by up-to 1.5 μm to expose only the Cu pads/pillars 126 used for Cu—Cu thermal compression bonding.

When a plurality of dielets 102 are bonded on substrate 104, the dielets can have a lateral dimension in a range of 0.5 mm to 10 mm, and a die/dielet thickness in a range of 10 μm to 500 μm. The dielets can have different architectures and functionalities, and can be manufactured in different process nodes. The plurality of dielets can be comprised of different materials and process flows depending on their functionalities (logic, memory, power etc.). As such, the dielets need to have same die/dielet thickness. The plurality of dielets can include metal layers that are terminated with Cu pads 130 as shown in FIG. 1.

The backside 122 of the substrate 104 may or may not be back-grinded to allow the fabrication of through silicon vias (TSVs) and backside redistribution layers (RDL) on the substrate, in case of substrate side power delivery. A thermal dissipation or heat extraction platform can extract heat from the assembly, placed on the side unused by power/signal platform.

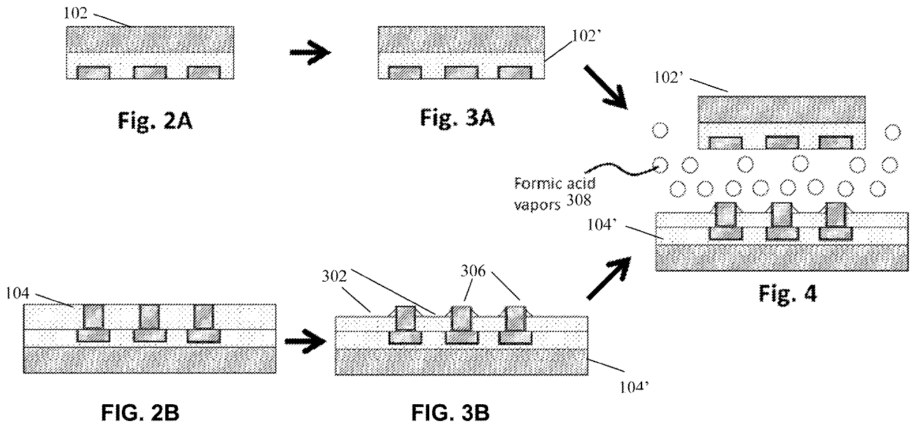

FIGS. 2 through 7 illustrate aspects of an example high throughput face-to-face heterogeneous dielet bonding process to be used in dielet assembly on interposers, wafer-scale and other advanced packaging constructs.

FIG. 2A and illustrate an example die/dielet 102 and substrate 104, respectively, before the initiation of high throughput thermal compression bonding process. Only one die/dielet 102 is shown for ease of illustrating aspects of embodiments.

FIGS. 3A and 3B show the pre-bonding treatment to be done both on die 102 and substrate 104 side. FIG. 3A indicates either a plasma or a wet cleaning treatment on Cu pads on the die/dielet 102 to reduce particles and activate the Cu surface for bonding. FIG. 3B shows a processed substrate 104′ with ≤1.5 μm dielectric recesses 302 that expose the Cu pillars/pads 306 for bonding. The dielectric used should be etchable using dry or wet etching chemistry. This allows for recessed Cu pads/pillars 306 on substrate which enables Cu—Cu contact while avoiding dielectric contact during the tacking process.

FIG. 4 shows a cross-section of both processed die/dielet 102′ and substrate 104′ right before tacking in the bonding chamber where the system is flushed with formic acid vapor 308 to convert any residual copper oxide to copper formate. The copper formate is then dissociated at higher temperature (<150 °C) to expose pristine copper exactly before tacking.

High throughput thermal compression bonding has two stages: tacking and assembly-level annealing. In the tacking stage, heterogeneous dies/dielets are assembled on a silicon-substrate. These dies/dielets are determined by design team based on the application the packaged product serves to accomplish. There is no constraint placed on the type of die/dielet 102 being placed except two: they preferably have the same die-thickness and they should terminate in their last Cu metal layer for Cu—Cu thermal compression bonding. The substrate 104 front side has Cu pads/pillars embedded in a dielectric.

FIG. 5 shows an example process of tacking of a die/dielet 102′ with Cu pads to Cu pillars on the substrate 104′ with necessary alignment. In embodiments, die-to-substrate alignment is done at a temperature ≤150 °C.

Die-to-substrate alignment may be done using any first order or second order alignment process. A standard die-to-substrate bonder with camera-based vision system can be used for tacking optimization. The parameters found to affect the tacking process are 1) actual tacking time, 2) time for dielet-to-substrate alignment; 3) time for dielet in-situ cleaning using formic acid vapor process; 4) tacking temperature; and 5) tacking pressure. The dielet transfer time including dielet pick and transfer to bond-head is absorbed into the overall dielet tacking time as it is a parallel process where every subsequent dielet is being picked and transferred while the previous dielet is undergoing tacking. The tacking stage is optimized to be completed in ≤10 seconds/dielet. Tacking is done either in air or nitrogen gas ambient.

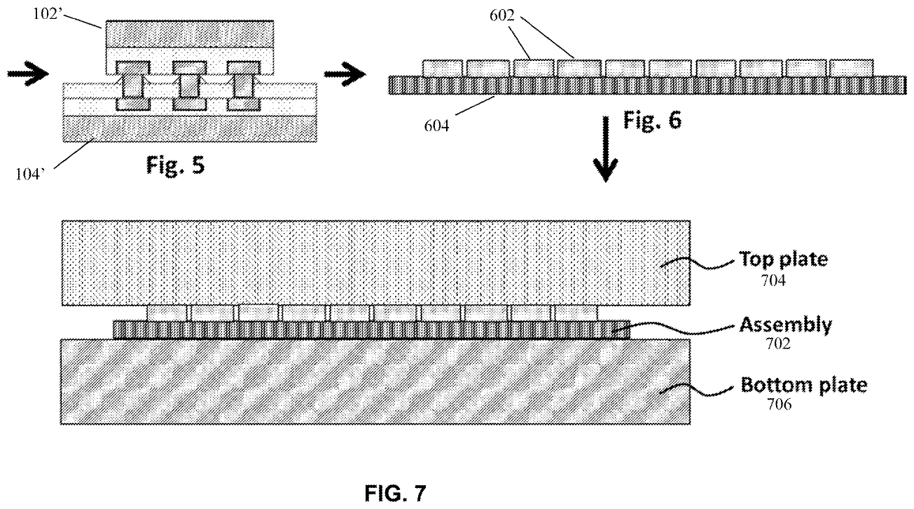

FIG. 6 illustrates a wafer-scale substrate 604, or an interposer substrate 604 populated with multiple dielets 602 ready to be annealed.

As shown in this example, a completely tacked assembly may include one or more die/dielets 602 on a single substrate 604. In case of an assembly with greater than one die/dielet, they may not be identical in architecture, circuit design, manufacturing process node or materials used in fabrication. Embodiments need not differentiate between die/dielets as long as they are back grinded to the same die thickness, which is preferred for assembly level annealing.

FIG. 7 shows an example wafer-scale system in the process of annealing after high throughput die/dielet placement on silicon-interconnect fabric (Si-IF) wafer-scale packaging substrate. The number of such wafer scale systems to be bonded simultaneously depend on annealing chamber infrastructure. Following this step, high-throughput bonding process is complete.

As shown in the example of FIG. 7, once all required die/dielets are tacked to the substrate, the assembly 702 is annealed. The parameters found to affect anneal are 1) anneal temperature, 2) anneal pressure and 3) anneal time. These parameters can be optimized to achieve military standard mechanical and electrical reliability of the bonded Cu—Cu contacts. In the example of FIG. 7, annealing pressure is applied using a top plate 704, and annealing temperature is applied on dielet and/or substrate side via top plate 704 and/or bottom plate 706. In one example assembly 702 is annealed at temperatures ≤450 °C.

After annealing, the assembly 702 can be separated into multiple assemblies and/or encapsulated. The encapsulating materials can be formed by physical vapor deposition (PVD), chemical vapor deposition (CVD), or atomic layer deposition (ALD). The encapsulating layers can have multiple layers with different materials by different methods of deposition. The encapsulating layers have a thickness in a range of 1 nm to 100 μm.

As set forth above, the assembly can include a power/signal delivery architecture that allows power/signal delivery to the assembled dielets using metal vias connecting to metal pads either on dielet/substrate-front side or on substrate back side. The metal vias can be through silicon vias (TSVs) in case of substrate side power delivery and through dielectric vias (TDVs) in case of dielet side or front side power delivery. The power/signal delivery architecture allows power/signal delivery to assembled dielets using pads at the substrate periphery.

As further set forth above, the assembly can include a thermal dissipation platform, wherein the heat extraction might be done using air cooling, water cooling or two-phase cooling depending on thermal requirements of the assembly. The thermal dissipation platform can be placed on the opposite side of power/signal delivery platform.

The herein described subject matter sometimes illustrates different components contained within, or connected with, different other components. It is to be understood that such depicted architectures are illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably coupleable,” to each other to achieve the desired functionality. Specific examples of operably coupleable include but are not limited to physically mateable and/or physically interacting components and/or wirelessly interactable and/or wirelessly interacting components and/or logically interacting and/or logically interactable components.

With respect to the use of plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general, such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Further, unless otherwise noted, the use of the words “approximate,” “about,” “around,” “substantially,” etc., mean plus or minus ten percent.

Although the present embodiments have been particularly described with reference to preferred examples thereof, it should be readily apparent to those of ordinary skill in the art that changes and modifications in the form and details may be made without departing from the spirit and scope of the present disclosure. It is intended that the appended claims encompass such changes and modifications.

1. An assembly comprising:
a substrate having a front side and a backside;
a front side of the substrate with patterned metal layers terminating with metal pads/pillars;
a dielectric layer surrounding the terminating metal pads/pillars which are partially recessed; and
a plurality of dielets which are face-to-face bonded on the recessed metal pads/pillars of the substrate using two-stage thermal compression bonding (TCB) to manufacture the assembled system.

2. The assembly of claim 1, further comprising:
an encapsulating material;
a power/signal platform which may be placed either on below or above the assembly to transfer power and signals to the assembled dielets;
a power/signal delivery platform placed below the assembly or above the assembly;
the backside of the substrate is back-grinded to allow the fabrication of through silicon vias (TSVs) and backside redistribution layers (RDL) on the substrate;
a dielectric filling the gaps between assembled dies/dielets on the frontside of the substrate to allow the fabrication of through dielet vias (TDVs) enabling a front-side or dielet-side power delivery; and
a thermal dissipation or heat extraction platform to extract heat from the assembly, placed on the side unused by power/signal platform.

3. The assembly of claim 1, wherein the substrate is a silicon substrate.

4. The assembly of claim 1, wherein the patterned metal layers include wires for lateral inter-die communication, and are terminated with metal vias, pillars, or pads.

5. The assembly of claim 1, wherein the patterned metal layers include power and ground planes or grids.

6. The assembly of claim 5, wherein the wires are in dedicated layers or are shared with part of the power and ground planes or grids.

7. The assembly of claim 6, wherein the power and ground planes or grids are connecting to metal vias, pillars, or pads.

8. The assembly of claim 7, wherein the metal vias, pillars, or pads are terminated on the top surface of the front side of the substrate with the material Copper (Cu).

9. The assembly of claim 7, wherein the metal vias, pillars, or pads are terminated on the top surface of the front side of the substrate with the material Copper (Cu).

10. The assembly of claim 7, wherein the metal vias, pillars, or pads are comprised of an additional layer of patterned metal for the electrical connection for an electroplating process.

11. The assembly of claim 1, wherein the dielets have a lateral dimension in a range of 0.5 mm to 10 mm, and a die/dielet thickness in a range of 10 μm to 500 μm.

12. The assembly of claim 1, wherein the dielets comprise different architectures and functionalities.

13. The assembly of claim 1, wherein the dielets are manufactured in different process nodes.

14. The assembly of claim 1, wherein the dielets comprise different materials and process flows depending on their functionalities, wherein the functionalities comprise at least logic, memory and power.

15. The assembly of claim 1, wherein the dielets all have a same die/dielet thickness.

16. The assembly of claim 1, wherein the dielets include metal layers terminated with Cu.

17. The assembly of claim 1, wherein the substrate comprises Cu pads/pillars not used for thermal compression bonding and are buried in dielectric prior to bonding.

18. The assembly of claim 1, wherein the substrate comprises Cu pads/pillars used for thermal compression bonding and are surrounded by a dielectric.

19. The assembly of claim 18, wherein dielectric is recessed by up-to 1.5 μm to expose only the Cu pads/pillars used for Cu—Cu thermal compression bonding.

20. A method of manufacturing the assembly of claim 1, comprising:
a face-to-face high throughput thermal compression bonding process; and
a pre-bonding step including formic acid vapor cleaning of exposed bondable Cu pads on dielet and Cu pads/pillars on substrate.

21. The method of claim 20, wherein die-to-substrate tacking time is ≤10 seconds.

22. The method of claim 20, wherein die-to-substrate alignment is done at a temperature ≤150 °C.

23. The method of claim 20, wherein die-to-substrate alignment may be done using a first order or second order alignment process.

24. The method of claim 20, wherein tacking is done either in air or nitrogen gas ambient.

25. The method of claim 20, wherein the assembly consists of a singularity or plurality of dielets from claim 13.

26. The method of claim 20, wherein annealing pressure is applied using a top plate, and annealing temperature is applied both on dielet and substrate side.

27. The method of claim 20, wherein the assembly is annealed at temperatures ≤450 °C.

28. A system comprising:
the assembly of claim 1;
an encapsulating material surrounding the assembly, wherein the encapsulating materials can be formed by physical vapor deposition (PVD), chemical vapor deposition (CVD), or atomic layer deposition (ALD).

29. The system of claim 28, wherein the encapsulating layers can have multiple layers with different materials by different methods of deposition.

30. The system of claim 28, wherein the encapsulating layers have a thickness in a range of 1 nm to 100 μm.

31. The system of claim 28, further comprising a power/signal delivery architecture that allows power/signal delivery to the assembled dielets using metal vias connecting to metal pads either on dielet/substrate-front side or on substrate back side.

32. The system of claim 31, wherein the metal vias are through silicon vias (TSVs) in case of substrate side power delivery and through dielectric vias (TDVs) in case of dielet side or front side power delivery.

33. The system of claim 31, wherein the power/signal delivery architecture provides power/signal delivery to assembled dielets using pads at the substrate periphery.

34. The system of claim 31, further comprising a heat extraction platform using air cooling, water cooling or two-phase cooling depending on thermal requirements of the assembly.

35. The substrate of claim 34, wherein the heat extraction platform is placed on the opposite side of a power/signal delivery platform.
